(19) United States
(12) Patent Application Publication
(10) Pub. No.: US 2026/0149204 A1
(43) Pub. Date: May 28, 2026

(54) CONNECTOR AND ACCESSORY FOR ELECTRONIC DEVICE

(71) Applicant: DONGGUAN LEADER PRECISION INDUSTRY CO., LTD., Dongguan City (CN)

(72) Inventors: Xunxu ZHANG, Dongguan City (CN); Xiaoqing ZHANG, Dongguan City (CN); Hongqiang XU, Dongguan City (CN)

(73) Assignee: DONGGUAN LEADER PRECISION INDUSTRY CO., LTD., Dongguan City, Guangdong Province (CN)

(21) Appl. No.: 19/403,689

(22) Filed: Nov. 28, 2025

(30) Foreign Application Priority Data
Nov. 28, 2024 (CN) 202411734845.3

(51) Int. Cl. H01R 12/72; H01R 12/70; H01R 13/24; H01R 13/504; H01R 13/6581

(52) U.S. Cl. CPC H01R 12/727; H01R 12/7047; H01R 12/7082; H01R 13/24; H01R 13/504; H01R 13/6581

(57) ABSTRACT

Disclosed are a connector and an accessory for an electronic device. The connector is assembled and connected to a circuit board, has a first end and a second end disposed opposite to each other, and includes: an insulating structure and a shielding structure that is disposed at the first end and is connected to the insulating structure; a shell structure sleeved on an outer side of the insulating structure, adhering to the circuit board, and disassemblably connected to the circuit board through a fastener; and a terminal assembly, part of a structure of which is disposed in the insulating structure, the terminal assembly including multiple sets of first conductive terminals and multiple sets of second conductive terminals that are located at the second end. The first conductive terminals and the second conductive terminals extend out of the insulating structure and are alternately arranged along a first direction of the connector.

### CROSS-REFERENCE TO RELATED APPLICATIONS

The present disclosure claims all the benefits of Chinese Patent Application No. 202411734845.3 filed on Nov. 28, 2024 before the China National Intellectual Property Administration of the People's Republic of China, entitled “Connector and Accessory for Electronic Device”, which is explicitly incorporated herein by reference in its entirety.

### FIELD

The present disclosure relates to the technical field of electronic devices, particularly to a connector and an accessory for an electronic device.

### BACKGROUND

In an electronic manufacture industry, welding of a connector is a key link to ensure a stable connection between electronic components. Conventional welding methods for the connector mainly include surface mounted technology (SMT), dual in-line package (DIP), and a combined form of the SMT and the DIP. These welding methods have their own advantages, and are suitable for different types of electronic products and manufacturing needs.

SMT welding is a modern electronic assembly technology which achieves an electrical connection and a mechanical fixing by directly mounting the connector on a surface of a printed circuit board (PCB) and solidifying a solder paste in a high-temperature furnace. SMT welding has advantages such as high efficiency, precision, and space saving, and is suitable for high-density and miniaturized electronic products.

DIP welding is a traditional electronic packaging method, which forms a firm electrical connection by inserting pins of the connector into jacks on a PCB and then undergoing solder paste solidification and high-temperature furnace heating. DIP welding has characteristics such as a large pin pitch, a good heat dissipation performance, and easy maintenance, and is suitable for electronic products with certain requirements for a pin pitch and a heat dissipation performance.

In some cases, to meet more complex connection needs, manufacturers adopt a combined welding method of SMT and DIP. The method combines advantages of the SMT and the DIP welding methods, not only achieving mounting of the connector on the surface of the PCB, but also enhancing firmness of the connection by inserting the pins into the jacks. However, the SMT, the DIP, and the SMT and DIP welding methods all have some inherent problems and limitations.

### SUMMARY

In a first aspect, the present disclosure provides a connector assembled and connected to a circuit board, and having a first end and a second end disposed opposite to each other, the connector including:
an insulating structure and a shielding structure that is disposed at the first end and is connected to the insulating structure;
a shell structure sleeved on an outer side of the insulating structure, adhering to the circuit board, and disassemblably connected to the circuit board through a fastener; and
a terminal assembly, part of a structure of which is disposed in the insulating structure, the terminal assembly including multiple sets of first conductive terminals and multiple sets of second conductive terminals, wherein the first conductive terminals and the second conductive terminals are located at the second end, extend out of the insulating structure, and are alternately arranged along a first direction of the connector, the first direction of the connector being perpendicular to a thickness direction of the connector
wherein a first side portion of the circuit board is provided with a conductive plate, the connector is embedded in the circuit board, and the first conductive terminals and the second conductive terminals are in contact-type electrical connection with the conductive plate.

In a second aspect, the present disclosure provides an accessory for an electronic device, including a fastener, a circuit board, and the connector according to the first aspect, wherein the fastener passes through the shell structure of the connector and is disassemblably connected to the circuit board;
the circuit board has a first side portion, the first side portion is provided with an accommodating space, the accommodating space penetrates through the circuit board along a thickness direction of the circuit board, and a side wall surface of the accommodating space disposed opposite to the first side portion is provided with a conductive plate; and
the accommodating space is configured to accommodate the connector, and the terminal assembly of the connector is in contact-type electrical connection with the conductive plate.

### BRIEF DESCRIPTION OF THE DRAWINGS

FIG. 1 is a schematic structure diagram of a connector and a circuit board provided by an embodiment of the present disclosure;

FIG. 2 is a schematic structure diagram of a connector provided by an embodiment of the present disclosure;

FIG. 3 is an exploded schematic diagram of a connector provided by an embodiment of the present disclosure;

FIG. 4 is a schematic structure diagram of a first conductive terminal provided by an embodiment of the present disclosure;

FIG. 5 is a schematic structure diagram of a second conductive terminal provided by an embodiment of the present disclosure;

FIG. 6 is a schematic structure diagram of a terminal assembly provided by an embodiment of the present disclosure;

FIG. 7 is a schematic structure diagram of an isolating seat provided by an embodiment of the present disclosure;

FIG. 8 is a top view of a connector provided by an embodiment of the present disclosure;

FIG. 9 is a sectional view along a line A-A shown in FIG. 8;

FIG. 10 is a schematic structure diagram of an outer shielding member provided by an embodiment of the present disclosure;

FIG. 11 is a schematic structure diagram of an intermediate shielding member provided by an embodiment of the present disclosure;

FIG. 12 is a schematic structure diagram of a first insulating member provided by an embodiment of the present disclosure;

FIG. 13 is a schematic structure diagram of a second insulating member provided by an embodiment of the present disclosure;

FIG. 14 is a schematic structure diagram of a third insulating member provided by an embodiment of the present disclosure;

FIG. 15 is a schematic structure diagram of a shell structure provided by an embodiment of the present disclosure; and

FIG. 16 is a schematic structure diagram of a circuit board provided by an embodiment of the present disclosure.

### DETAILED DESCRIPTION

In order to make objects, technical solutions, and advantages of embodiments of the disclosure clearer, the technical solutions in the embodiments of the disclosure will be clearly and fully described in combination with the accompanying drawings in the embodiments of the present disclosure. Obviously, the embodiments to be described are part of embodiments but not all embodiments of the disclosure. Based on the embodiments of the disclosure, all other embodiments obtained by those of ordinary skill in the art without inventive work shall fall within the scope of the disclosure.

Many different embodiments or examples are disclosed below to realize different structures of the disclosure. In order to simplify the disclosure, components and arrangements of specific examples are described below. Of course, they are only exemplary and are not intended to limit the disclosure. Furthermore, the present disclosure may repeat reference numerals and/or letters in different examples. The repetition is for simplicity and clarity, and in itself does not indicate the relationship between the various embodiments and/or arrangements discussed.

For the convenience of description, spatial relationship terms can be used herein to describe the relative positional relationship or rotation of one element or feature relative to another element or feature as shown in the drawings, such as “inside”, “outside”, “inner”, “outer”, “under”, “below”, “on”, “above”, “front” and “back”. This spatial relationship term is intended to include different orientations of the device in use or operation other than orientations depicted in the drawings. For example, if the device in the drawings has a position turnover, a posture change or a movement state change, these directional indications will change accordingly. For example, elements described as “under or below other elements or features” will be subsequently oriented as “on or over other elements or features”. Thus, the exemplary term “below” may include both orientations of above and below. The device may be otherwise oriented (rotated by 90 degrees or in other directions), and the spatial relationship description used herein are interpreted accordingly.

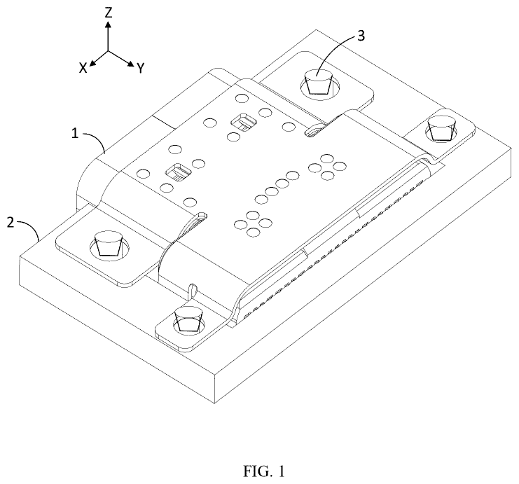

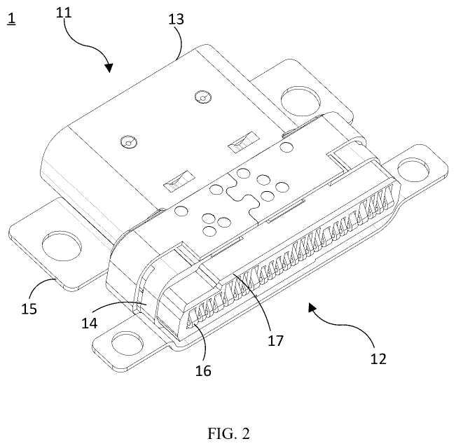

In some exemplary embodiments, as shown in FIG. 1 to FIG. 3, a connector 1 is applied in an electronic device to facilitate stable transmission and efficient connection of internal signals. A plurality of accessories are built in the electronic device to support normal use of the electronic device, such as including but not limited to a circuit board 2 and the connector 1. The connector 1 is assembled and connected to the circuit board 2 to ensure the stable transmission and the efficient connection of the internal signals of the electronic device. Alternatively, the connector 1 is plugged into another connector in the electronic device to achieve signal transmission, for example, the connector 1 in the present disclosure is a female connector, and a male connector is provided in the electronic device, and the two are plugged and connected.

The connector 1 has a first end 11 and a second end 12 disposed opposite to each other. The first end 11 is, for example, a head portion, that is, an end that forms a precise plug-in connection with the male connector, ensuring seamless transmission of signals. The second end 12 is, for example, a tail portion, that is, an end connected to the circuit board 2, to construct an internal signal network of the electronic device.

The connector 1 includes a shielding structure 13, an insulating structure 14, a shell structure 15, and a terminal assembly 16, which cooperate together to provide a stable and reliable signal connection for the electronic device.

The shielding structure 13 is disposed at the first end 11 and is connected to the insulating structure 14, forming an effective electromagnetic shielding layer, which effectively isolates external electromagnetic interference and ensures pure transmission of internal signals of the connector 1. A partial position of the insulating structure 14 may play a supporting role for the shielding structure 13 to ensure stable operation of the shielding structure 13.

The insulating structure 14 is, for example, made of a material with an insulating performance, and may isolate different signal terminals within the terminal assembly 16 from each other to prevent signal crosstalk, while supporting and fixing the terminal assembly 16 and the shielding structure 13.

The shell structure 15 is sleeved on an outer side of the insulating structure 14, which not only enhances mechanical strength of the connector 1, but also provides an additional protective barrier to prevent external factors from causing damage to an interior of the connector 1. Moreover, the insulating structure 14 may also provide partial support for the shell structure 15 to provide mechanical strength for the shell structure 15, and the shell structure 15 may provide protection, avoiding external interference with an interior thereof and improving overall stability and safety thereof.

The shell structure 15 adheres to the circuit board 2 and is disassemblably connected to the circuit board 2 through a fastener 3, improving convenience when installing and disassembling the connector 1. The fastener 3 is, for example, a bolt or a screw, which may improve stability during installation, and it is more convenient to replace the connector 1.

Part of the structure of the terminal assembly 16 is embedded in the insulating structure 14 to fix the terminal assembly 16, ensuring stability of the terminal assembly 16 and preventing the terminal assembly 16 from being unable to form an aligned connection with the male connector due to shaking or shifting. Another part of the structure is in an exposed state to facilitate connection with the male connector or the circuit board 2 to achieve signal transmission.

The terminal assembly 16 includes multiple sets of first conductive terminals 161 and multiple sets of second conductive terminals 162, the first conductive terminals 161 and the second conductive terminals 162 disposed at the second end 12 extend out of the insulating structure 14 and are alternately arranged along a first direction of the connector 1, ensuring efficiency and stability of signal transmission. The first conductive terminals 161 and the second conductive terminals 162 avoid each other and form a regular arrangement, and, outermost edges of the first conductive terminals 161 and the second conductive terminals 162 are in a flush state along a second direction of the connector 1, which may ensure an electrical connection between the terminal assembly 16 and the circuit board 2, and meet high-frequency requirements of Universal Serial Bus (USB) 4.0.

The connector 1 has a first direction (referring to an X-axis shown in FIG. 1), a second direction (referring to a Y-axis shown in FIG. 1), and a thickness direction (referring to a Z-axis shown in FIG. 1). The first direction is, for example, a width direction of the connector 1, the second direction is, for example, a length direction of the connector 1, and the first direction, the second direction, and the thickness direction are perpendicular to each other.

A conductive plate 22 is disposed on a first side portion 24 of the circuit board 2, and the connector 1 is embedded in the circuit board 2, which is conducive to optimizing a size in the thickness direction and reducing an overall thickness. Moreover, the first conductive terminals 161 and the second conductive terminals 162 are in a contact-type electrical connection with the conductive plate 22 of the circuit board 2; compared with a welding method in the related art, a connection method in the present disclosure is simple and may effectively reduce a surface mounting technology process and labor, making operation of the process smoother and effectively improving production efficiency. Furthermore, the contact-type connection does not need to go through a high-temperature welding process, effectively avoiding a problem of material deformation that may be caused by high-temperature welding.

Both side surfaces of the circuit board 2 are lower than a surface of the connector 1 along the thickness direction of the connector 1, so that the connector 1 is completely embedded in the circuit board 2, which optimizes an overall thickness after assembly, helps to promote thin-profile development of electronic devices, and meets modern consumers' needs for thin and light products.

The contact-type connection between the connector 1 and the circuit board provided by the embodiment eliminates a welding process and effectively reduces a surface adhering technology process and labor costs, making operation smoother and improving production efficiency. Moreover, because the welding-free manner does not need to undergo a heating process of a high-temperature furnace, the connector is not deformed, thereby ensuring the performance and reliability of the connector. If the connector needs to be replaced, the connector is easily disassembled by simply removing a fastener, without complicated welding operation, which is convenient and fast. In addition, the thickness of the connector 1 is less than the thickness of the circuit board 2, which is conducive to achieving a thinning design of the electronic device.

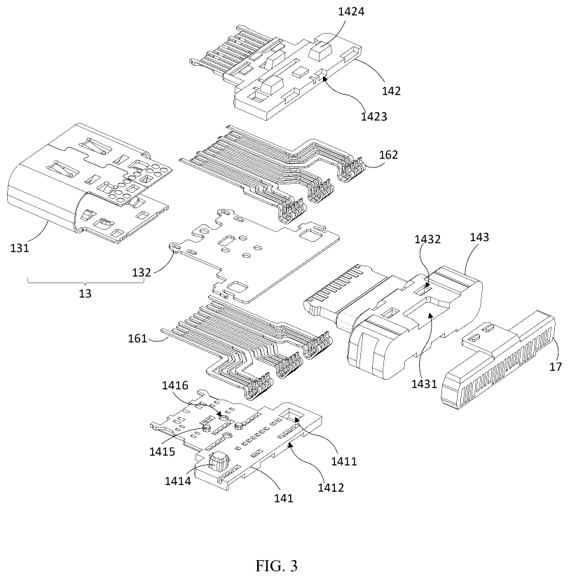

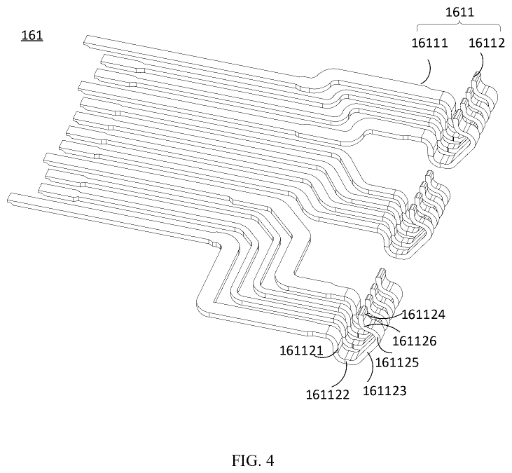

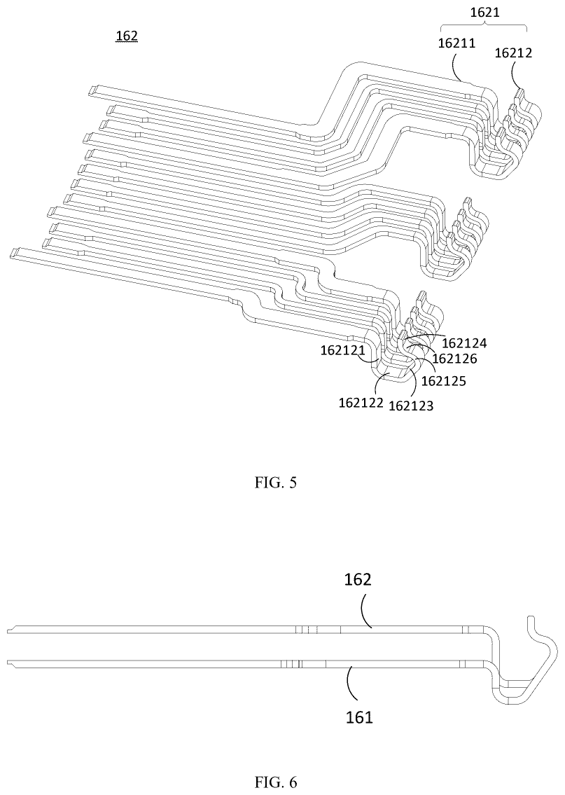

In some exemplary embodiments, as shown in FIG. 3 to FIG. 6, the first conductive terminal 161 includes a plurality of first conductive bodies 1611 sequentially arranged at intervals along the first direction of the connector 1. For example, four first conductive bodies 1611 are provided and may have the same shape or different shapes. The shape, for example, may be a width, a length, and an extension path of the first conductive body 1611. Moreover, a signal function of each of the first conductive bodies 1611 may be the same or different, which is subject to actual situations.

The first conductive body 1611 includes a first main body 16111 and a first elastic arm 16112, the first main body 16111 is connected to the first elastic arm 16112, and the first elastic arm 16112 is configured to abut against the circuit board 2. The first main body 16111 is embedded in the insulating structure 14, and may be bent to extend along the first direction or the second direction to change an extension path of the first main body 16111, thereby avoiding each other, forming orderly arrangement, and avoiding mutual interference.

It should be noted that, a width of two adjacent first main bodies 16111 may be designed based on a signal transmission situation, and widths at different positions of the single first main body 16111 may also be the same or different, which is subject to actual situations.

The first elastic arm 16112 extends out of the insulating structure 14 to facilitate a contact-type connection with the circuit board 2 to meet the signal transmission.

In the embodiment, as shown in FIG. 3 to FIG. 6, the first elastic arm 16112 includes a first bending section 161121, a first straight section 161122, a first inclined section 161123, and a second bending section 161124, which are sequentially connected. The first bending section 161121 bends relative to the first main body 16111 and extends along the thickness direction of the connector 1, that is, serves as a starting portion of the first elastic arm 16112 and extends downward. The first straight section 161122 bends relative to the first bending section 161121 and extends along the second direction of the connector 1, that is, extends in a direction away from the first main body 16111, to extend an overall length of the first elastic arm 16112 along the second direction, so as to ensure that the first elastic arm 16112 can abut against the circuit board 2, and to provide a basis for subsequent inclination and bending.

It should be noted that, descriptions of orientations in the present disclosure, such as up and down, are for ease of understanding and description, and are all exemplarily illustrated based on orientations in the drawings, and do not constitute a limitation on the present disclosure.

The first inclined section 161123 is inclined relative to the first straight section 161122, that is, inclined upward, so that the first inclined section 161123 and the first straight section 161122 form a first preset included angle that is, for example, any value from 100° to 150°. A larger degree of the first preset included angle may better ensure a tighter contact-type connection between the first elastic arm 16112 and the circuit board 2.

An extension direction of the first inclined section 161123 and an extension direction of the first bending section 161121 show an opposite trend, that is, the first bending section 161121 has a downward extension trend, and the first inclined section 161123 has an upward inclination trend, forming a turning path, which may ensure that a size of the first elastic arm 16112 in the thickness direction of the connector 1 is not too large, is conducive to reducing an overall thickness of the connector 1, and achieves a compact design.

The second bending section 161124 bends relative to the first inclined section 161123 and extends along the thickness direction of the connector 1, that is, extends in a vertical direction, which may increase an abutment surface of the second bending section 161124 and improve connection stability. Each turning connection position in the first elastic arm 16112 is chamfered to reduce sharp parts, effectively avoiding damage to other components of the connector 1.

Exemplarily, the first elastic arm 16112, for example, includes a first turning arc section 161125 and a second turning arc section 161126, the first inclined section 161123 is connected to the first turning arc section 161125, the first turning arc section 161125 is configured to be chamfered for the first time, and the first turning arc section 161125 is configured to abut against the circuit board 2 to form a contact-type connection with the circuit board 2. A recess of the first turning arc section 161125 is located on a side away from the circuit board 2, so that an arc surface of the first turning arc section 161125 may form elastic abutment against the circuit board 2, avoiding damage to the circuit board 2 and improving connection safety.

The first turning arc section 161125 is connected to the second turning arc section 161126, the second turning arc section 161126 is configured to be chamfered for the second time, and a recess orientation of the first turning arc section 161125 is opposite to a recess orientation of the second turning arc section 161126, that is, a recess of the second turning arc section 161126 faces a side of the circuit board 2.

The second turning arc section 161126 is connected to the second bending section 161124, and the second bending section 161124 extends upward, thereby changing the extension path of the first elastic arm 16112. The second bending section 161124 is a free end of the first elastic arm 16112. When the first elastic arm 16112 is pressed by the circuit board 2, that is, the first turning arc section 161125 is pressed, the first elastic arm 16112 is deformed, and the first turning arc section 161125 drives the first inclined section 161123 and the first turning arc section 161125 to move, thereby changing a degree of the first preset included angle and a position of the second bending section 161124. The second bending section 161124 will eventually abut against other components of the connector 1 to prevent further movement of the second bending section 161124, thereby ensuring that the second turning arc section 161126 and the circuit board 2 are always in a contact state, and enhancing dynamic stability and adaptability of the connection.

It should be noted that, chamfering is not limited to be performed between the first inclined section 161123 and the second bending section 161124 in the first elastic arm 16112; chamfering may also be performed between the first bending section 161121 and the first straight section 161122, and between the first straight section 161122 and the first inclined section 161123, which reduces sharp parts, avoids damage to the circuit board 2 or other components during connection, and improves connection safety.

In some exemplary embodiments, as shown in FIG. 3 to FIG. 6, the second conductive terminal 162 includes a plurality of second conductive bodies 1621, and the plurality of second conductive bodies 1621 are sequentially arranged at intervals along the second direction of the connector 1. For example, four second conductive bodies 1621 are provided, and shapes of the four second conductive bodies 1621 may be the same or different. The shape, for example, may be a width, a length, and an extension path of the second conductive body 1621. Moreover, signal functions of the second conductive bodies 1621 may be the same or different, which is subject to actual situations.

The second conductive body 1621 includes a second main body 16211 and a second elastic arm 16212, and the second main body 16211 is disposed opposite to the first main body 16111 along the thickness direction of the connector 1 to optimize a space layout and reduce mutual interference between signals.

The second main body 16211 is connected to the second elastic arm 16212, the second main body 16211 is embedded in the insulating structure 14, and the second elastic arm 16212 extends out of the insulating structure 14 and abuts against the circuit board 2 to facilitate a contact-type connection with the circuit board 2 to meet the signal transmission. The second main body 16211 may be bent to extend along the first direction or the second direction to change an extension path of the second main body 16211, thereby avoiding each other, forming an orderly arrangement, and avoiding mutual interference.

It should be noted that, between two adjacent second main bodies 16211, a width of the two adjacent second main bodies 16211 may be designed based on a signal transmission situation, and at different positions of a single second main body 16211, the single second main body 16211 may have different or same widths, which is subject to actual situations.

A projection area of the second elastic arm 16212 along the first direction of the connector 1 at least partially overlaps a projection area of the first elastic arm 16112 along the first direction of the connector 1, so that the second elastic arm 16212 and the first elastic arm 16112 are kept on a same plane, ensuring that the second elastic arm 16212 and the first elastic arm 16112 may simultaneously form a contact-type connection with the circuit board 2.

In the embodiment, as shown in FIG. 3 to FIG. 6, the second elastic arm 16212 includes a third bending section 162121, a second straight section 162122, a second inclined section 162123, and a fourth bending section 162124 which are sequentially connected. The third bending section 162121 bends relative to the second main body 16211 and extends along the thickness direction of the connector 1, that is, serves as a starting portion of the second elastic arm 16212 and extends downward.

The second straight section 162122 bends relative to the third bending section 162121 and extends along the second direction of the connector 1, that is, extends in a direction away from the second main body 16211 and extends an overall length of the second elastic arm 16212 along the second direction, so as to ensure that the second elastic arm 16212 can abut against the circuit board 2, and to provide a basis for subsequent inclination and bending.

A projection area of the second straight section 162122 along the first direction of the connector 1 does not overlap the projection area of the first elastic arm 16112 along the first direction of the connector 1, so that a staggered arrangement is formed between the second straight section 162122 and the first straight section 161122 of the first elastic arm 16112, avoiding each other. An extension length of the third bending section 162121 and an extension length of the first bending section 161121 are different, thereby forming a staggered design between the second straight section 162122 and the first straight section 161122. In practical applications, it is only necessary to meet respective stresses of the second elastic arm 16212 and the first elastic arm 16112, therefore, a specific length of the second elastic arm 16212 and the first elastic arm 16112 is subject to actual situations.

The second inclined section 162123 is inclined relative to the second straight section 162122, that is, inclined upward, so that the second inclined section 162123 and the second straight section 162122 form a second preset included angle, for example, any value from 100° to 150°. The larger degree of the second preset included angle, the tighter contact-type connection between the second elastic arm 16212 and the circuit board 2.

An extension direction of the second inclined section 162123 and an extension direction of the third bending section 162121 show opposite trends, that is, the third bending section 162121 has a downward extension trend, and the second inclined section 162123 has an upward inclination trend, forming a turning path, which may ensure that a size of the second elastic arm 16212 in the thickness direction of the connector 1 is not too large, is conducive to reducing an overall thickness of the connector 1, and achieves a compact design.

The fourth bending section 162124 bends relative to the second inclined section 162123 and extends along the thickness direction of the connector 1, that is, extending in a vertical direction, which may increase an abutment surface of the fourth bending section 162124 and improve connection stability. Each turning connection position in the second elastic arm 16212 is chamfered to reduce sharp parts and effectively avoid damaging other components of the connector 1.

Exemplarily, the second elastic arm 16212 includes a third turning arc section 162125 and a fourth turning arc section 162126, the second inclined section 162123 is connected to the third turning arc section 162125, the third turning arc section 162125 is configured to be chamfered for the third time, and the third turning arc section 162125 abuts against the circuit board 2 to form a contact-type connection with the circuit board 2. A recess of the third turning arc section 162125 is located on a side away from the circuit board 2, so that an arc surface of the third turning arc section 162125 may form an elastic abutment with the circuit board 2, avoiding damage to the circuit board 2 and improving connection safety.

The third turning arc section 162125 is connected to the fourth turning arc section 162126, the fourth turning arc section 162126 is configured to be chamfered for the fourth time, and a recess orientation of the third turning arc section 162125 is opposite to a recess orientation of the fourth turning arc section 162126, that is, a recess of the fourth turning arc section 162126 faces a side of the circuit board 2.

The fourth turning arc section 162126 is connected to the fourth bending section 162124, and the fourth bending section 162124 extends upward, thereby changing the extension path of the second elastic arm 16212. The fourth bending section 162124 is a free end of the second elastic arm 16212; when the second elastic arm 16212 is pressed by the circuit board 2, that is, the third turning arc section 162125 is pressed, the second elastic arm 16212 is deformed, and the third turning arc section 162125 drives the second inclined section 162123 and the third turning arc section 162125 to move, thereby changing an angle of the second preset included angle and a position of the fourth bending section 162124. The fourth bending section 162124 will eventually abut against other components of the connector 1 to prevent further movement of the fourth bending section 162124, thereby ensuring that the fourth turning arc section 162126 and the circuit board 2 are always in a contact state, and enhancing a dynamic stability and an adaptability of the connection.

Projection areas of the third turning arc section 162125 and the fourth turning arc section 162126 along the first direction of the connector 1 overlap the projection area of the first elastic arm 16112 along the first direction of the connector 1, that is, a projection area of the third turning arc section 162125 along the first direction overlaps a projection area of the first turning arc section 161125 along the first direction, and a projection area of the fourth turning arc section 162126 along the first direction overlaps a projection area of the second turning arc section 161126 along the first direction, to ensure that a side of the first elastic arm 16112 and the second elastic arm 16212 away from the first end 11 is kept flush, and the first elastic arm 16112 and the second elastic arm 16212 simultaneously abut against the circuit board 2 to achieve an electrical connection.

It should be noted that, the chamfering treatment in the second elastic arm 16212 is not limited to be performed between the second inclined section 162123 and the fourth bending section 162124; the chamfering treatment may also be performed between the third bending section 162121 and the second straight section 162122, and between the second straight section 162122 and the second inclined section 162123, which reduces sharp parts, avoids damage to the circuit board 2 or other components during a connection process, and improves the connection safety.

In the embodiment, as shown in FIG. 3 to FIG. 6, the first elastic arm 16112 may be a barb-like structure to achieve an elastic abutment against the circuit board 2. A barb body of the barb-like structure bends to extend upward and a barb opening of the barb-like structure faces upward, to ensure that a projection of the first elastic arm 16112 in the second direction may fall within a boundary of the insulating structure 14, which effectively utilizes a thickness space of the connector 1 and avoids increasing an overall thickness of the connector 1, facilitating a thin-profile design of the connector 1. When the first conductive terminal 161 is in contact-type connection with the circuit board 2, the first elastic arm 16112 is deformed, and an opening of the barb opening becomes smaller.

It should be noted that, the second elastic arm 16212 may also be a barb-like structure, and a disposition manner of the second elastic arm 16212 is the same as or similar to that of the above-mentioned first elastic arm 16112. When the second conductive terminal 162 is in contact-type connection with the circuit board 2, the second elastic arm 16212 is also deformed, which is not repeated herein.

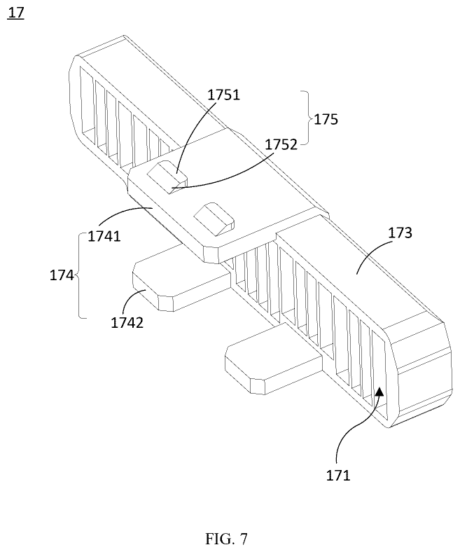

In some exemplary embodiments, as shown in FIG. 3 to FIG. 7, the connector 1 includes an isolating seat 17, the isolating seat 17 is provided with a plurality of first through-holes 171, and the first elastic arm 16112 and the second elastic arm 16212 are respectively inserted into the corresponding first through-holes 171 to separate adjacent first elastic arms 16112, adjacent second elastic arms 16212, or a first elastic arm 16112 and a second elastic arm 16212 adjacent to each other, and the like, so as to avoid a risk of an electrical connection short circuit caused by direct contact between the above-mentioned elastic arms.

The first through-hole 171 is, for example, rectangular, and has a sufficient accommodating space to place the first elastic arm 16112 or the second elastic arm 16212, ensuring that the first elastic arm 16112 or the second elastic arm 16212 can remain stable after being inserted, and is not easy to shake or fall off. Although each of the first through-holes 171 has a similar rectangular feature in structure, the first through-holes 171 exhibit a certain flexibility in size. For example, lengths of the first through-holes 171 may be the same, or may be different according to the need along the thickness direction of the connector 1; similarly, widths of the first through-holes 171 may also be consistent or different along the first direction of the connector 1. The flexibility in size enables the isolating seat 17 to better adapt to elastic arms of different sizes and shapes, further improving universality and practicability of the connector.

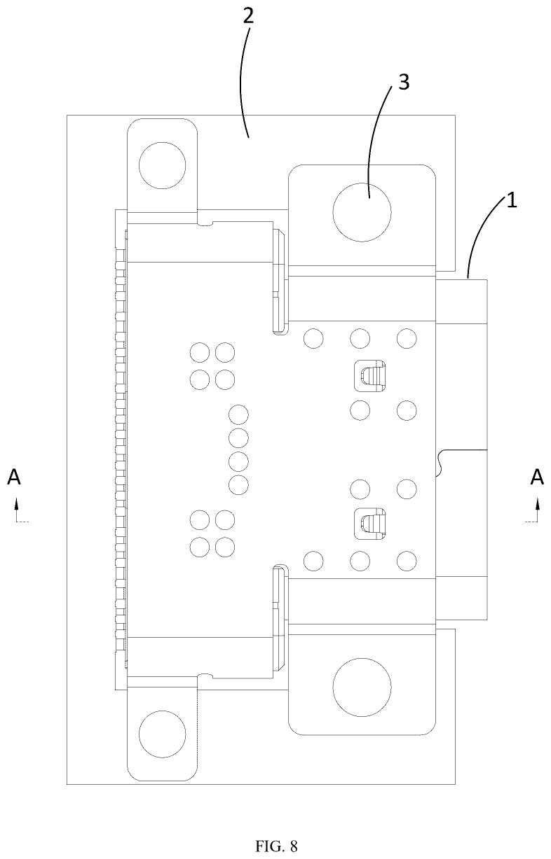

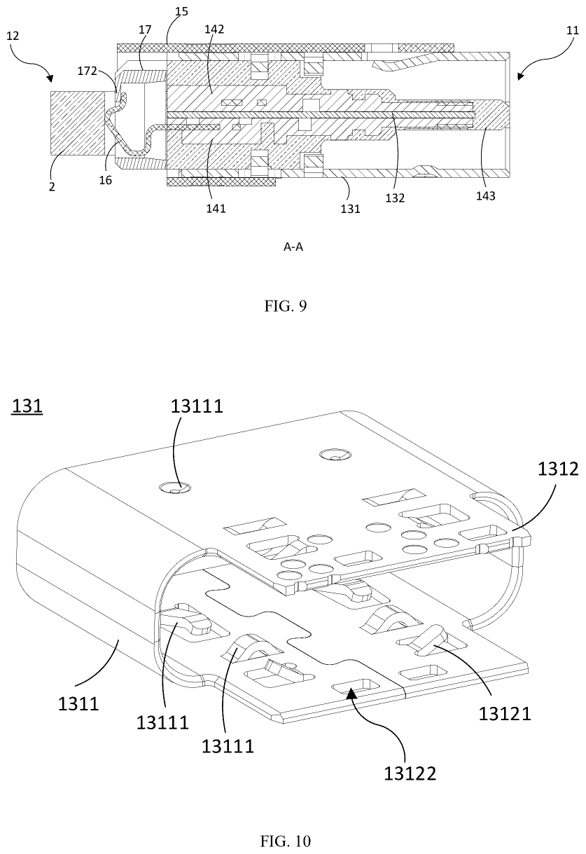

In the embodiment, as shown in FIG. 3 to FIG. 9, an inner side wall of the first through-hole 171 may also be provided with a blocking wall 172, and the blocking wall 172 is located on a side of the first through-hole 171 away from the insulating structure 14. Hereinafter, taking the first elastic arm 16112 as an example, a connection manner between the first elastic arm 16112 and the blocking wall 172 is further explained to avoid unnecessary contact with an adjacent elastic arm and ensure stability and safety of the connector 1.

When the first elastic arm 16112 is not pressed by the circuit board 2, the first elastic arm 16112 is reset, and the first turning arc section 161125 drives the first inclined section 161123 and the second turning arc section 161126 to move toward a side of the second end 12 to restore to an original position. The second bending section 161124 may abut against the blocking wall 172 to prevent further movement of the second bending section 161124 along the second direction, effectively preventing the second bending section 161124 from accidentally detaching from the first through-hole 171, and avoiding an electrical connection problem caused by the second bending section 161124 moving out of the first through-hole 171 and contacting an adjacent first elastic arm 16112 or second elastic arm 16212.

It may be understood that, a side of the first through-hole 171 at the first end 11 may also be provided with a similar blocking wall (not shown in the figure), and such a design may also effectively prevent further movement of the second bending section 161124 when the first elastic arm 16112 is pressed by the circuit board 2, preventing a gap or separation between the first elastic arm 16112 and the circuit board 2, thereby ensuring a good connection effect. A setting of the blocking wall may be flexibly selected according to actual situations to meet different application needs.

It should be noted that, a connection manner of the second elastic arm 16212 and the first through-hole 171 is the same as or similar to the connection manner of the above-mentioned first elastic arm 16112 and the first through-hole 171. This means that the second elastic arm 16212 is also limited by the blocking wall to prevent the second elastic arm 16212 from detaching from a preset position, thereby maintaining the stability and the safety of the connector 1. For a specific connection manner, refer to a description between the first elastic arm 16112 and the first through-hole 171, which is not repeatedly described herein.

The isolating seat 17 in the embodiment may effectively limit a movement range of the elastic arms, and prevent unnecessary contact and electrical connection problems; flexibly setting the blocking wall may improve stability, adaptability, and an overall performance of the connector 1, and also provide more convenience and guarantee for a user when selecting and using the connector 1.

In the embodiment, as shown in FIG. 3 to FIG. 7, the isolating seat 17 is disposed at the second end 12 and is connected to the insulating structure 14 to achieve an assembly connection and improve stability of the isolating seat 17 during installation.

The isolating seat 17, for example, includes an isolating body 173 and a connecting support body 174, and the connecting support body 174 is connected to the isolating body 173. The isolating body 173 is disposed at the second end 12 and is connected with the insulating structure 14 in close contact along the second direction of the connector 1, and the connecting support body 174 is connected with the insulating structure 14 in close contact along the thickness direction of the connector 1, to improve overall stationarity of the isolating body 173. There may be one connecting support body 174 or a plurality of connecting support bodies 174, which may be flexibly designed according to actual needs.

### First Example

The connecting support body 174 may be, for example, set as one, which is plate-like and attached to the insulating structure 14. The connecting support body 174 and the insulating structure 14 may be locked or snap-fit connected to prevent the isolating seat 17 from detaching.

### Second Example

For example, two connecting support bodies 174 are provided, and are disposed opposite to each other along the thickness direction of the connector 1, and each of the connecting support bodies 174 is fixedly connected to the isolating body 173. The two connecting support bodies 174 sandwich the insulating structure 14, improving stability of the isolating seat 17 and preventing the isolating seat 17 from shaking or misalignment during use, thereby ensuring an aligned installation accuracy of the first elastic arm 16112 or the second elastic arm 16212.

### Third Example

The connecting support body 174 includes a first connecting support body 1741 and two second connecting support bodies 1742, and the first connecting support body 1741 and the second connecting support bodies 1742 are disposed separately on two sides along the thickness direction of the connector 1. The first connecting support body 1741 may, for example, be close to a middle position of the isolating body 173, the two second connecting support bodies 1742 are arranged at intervals along the first direction of the connector 1, and the first connecting support body 1741 and the two second connecting support bodies 1742 achieve fixing at three different positions, which may further improve stability when the isolating seat 17 is installed to the insulating structure 14.

The insulating structure 14 is, for example, provided with an embedding groove 1431, and the number of the embedding grooves 1431 corresponds to the number of the connecting support bodies 174, so as to facilitate embedding of the first connecting support body 1741 and the second connecting support bodies 1742 into the corresponding embedding grooves 1431, which may not only achieve a positioning connection, but also ensure flatness during connection, avoiding an increase in the thickness of the connector 1.

In the embodiment, as shown in FIG. 3 to FIG. 7, the connecting support body 174 is provided with a limiting catch 175, and the connecting support body 174 is connected to the shielding structure 13 in a limiting manner through the limiting catch 175, which is easy to assemble and improves the convenience of installation and disassembly.

The limiting catch 175 is disposed on a side of the connecting support body 174 away from the insulating structure 14, and there may be, for example, one or two limiting clips 175, and the two limiting clips 175 are arranged at intervals. Exemplarily, the limiting catch 175 includes a limiting protruding body 1751 and a wedge 1752, the limiting protruding body 1751 protrudes from the connecting support body 174, and the limiting protruding body 1751 is fixedly connected to the wedge 1752. The wedge 1752 is located on a side of the limiting protruding body 1751 close to the first end 11 to facilitate connection with the shielding structure 13, and the shielding structure 13 is provided with a limiting through-hole matching with the limiting catch 175 to achieve a limiting plug-in connection.

During an installation process, the shielding structure 13 slides along a wedge-shaped surface of the wedge 1752, which makes the installation process smoother. When the limiting catch 175 completely enters the limiting hole 13122, the limiting protruding body 1751 and the limiting hole 13122 interfere with each other to prevent the limiting protruding body 1751 from detaching from the limiting hole 13122, improving reliability of a connection between the isolating seat 17 and the shielding structure 13.

In the embodiment, the isolating seat 17 and a connection manner of the isolating seat 17 with the insulating structure 14 and the shielding structure 13 significantly improve the stability and installation convenience of the connector 1, not only optimizing a connection structure, but also improving an overall performance and reliability of the connector 1.

In some exemplary embodiments, as shown in FIG. 3 to FIG. 10, the shielding structure 13 includes an outer shielding member 131 that has a tubular structure, so that the outer shielding member 131 may be sleeved on the insulating structure 14 to shield and isolate the outside, avoid electromagnetic interference, and ensure stability and quality of signal transmission.

The outer shielding member 131 includes a first portion 1311 and two second portions 1312, the first portion 1311 is a barrel structure, which not only enhances overall structure strength of the connector 1, but more importantly provides a continuous electromagnetic shielding layer for the connector 1, effectively blocking electromagnetic interference from the outside and protecting pure transmission of internal signals.

The first portion 1311 is located at the first end 11 and is spaced apart from the terminal assembly 16 of the connector 1 to ensure that a male connector is not obstructed during insertion. The first portion 1311 is provided with a plurality of contact spring arms 13111; when plugged with the male connector, the plurality of contact spring arms 13111 may abut against the male connector, so that the male connector is in close contact with the outer shielding member 131 or the terminal assembly 16, ensuring that signals can be transmitted normally.

Exemplarily, forms of the plurality of contact spring arms 13111 may be the same or different. For example, the contact spring arm 13111 may be, for example, in a shape of a hemispherical protrusion, and a smooth surface of the hemispherical protrusion may protect the male connector; or, the contact spring arm 13111 may be, for example, in a V-shape to effectively abut against the male connector, and a tip portion of the V-shape is rounded to avoid scratching the male connector, prolonging a service life of the male connector; or, the contact spring arm 13111 may be, for example, in a shape of a spring piece, a free end of the spring piece may abut against the male connector, and an abutment position of the free end is chamfered to avoid damaging the male connector, which optimizes a contact effect and prolongs a service life of the connector 1.

The two second portions 1312 are located at the second end 12 and are symmetrically disposed along the thickness direction of the connector 1, and each of the two second portions 1312 is connected to the insulating structure 14. Exemplarily, the second portion 1312 is provided with a limiting spring piece 13121, and may be disassemblably connected to the insulating structure 14 through the limiting spring piece 13121, and is installed in a limiting manner, effectively improving installation efficiency. There may be one limiting spring piece 13121 or a plurality of limiting spring pieces 13121. When there are a plurality of limiting spring pieces 13121, the plurality of limiting spring pieces 13121 are symmetrically disposed along the first direction of the connector 1 and/or symmetrically disposed along the thickness direction of the connector 1, to ensure balance and stability of installation. Moreover, the insulating structure 14 is provided with a limiting recess 1432 matching the limiting spring piece 13121, a fixed end of the limiting spring piece 13121 is connected to the second portion 1312, and a free end of the limiting spring piece 13121 may extend into the limiting recess 1432 to achieve a locking connection. When disassembly is required, the limiting spring piece 13121 may be deformed under an external force, so as to be easily detached from the limiting recess 1432, which greatly improves efficiency of installation and disassembly.

In the embodiment, as shown in FIG. 3 to FIG. 10, the connector 1 effectively improves electromagnetic compatibility and signal transmission quality through an optimized shielding structure 13. The second portion 1312 of the outer shielding member 131 is provided with at least one limiting hole 13122, and the limiting hole 13122 achieves a precise plug-in connection with the limiting catch 175, thereby achieving disassemblable assembly of the outer shielding member 131 to other components of the connector 1. The number of the limiting holes 13122 is consistent with the number of the limiting clips 175 to facilitate a one-to-one aligned plug-in connection, which not only simplifies an assembly process, but also enhances stability of the connection.

In the embodiment, as shown in FIG. 3 to FIG. 11, in order to further improve the electromagnetic compatibility of the connector 1, the shielding structure 13 further includes an intermediate shielding member 132, the intermediate shielding member 132 is disposed between the first main body 16111 of the first conductive terminal 161 and the second main body 16211 of the second conductive terminal 162, forming a physical barrier, effectively blocking electromagnetic interference between the first conductive terminal 161 and the second conductive terminal 162, and ensuring purity and stability of signal transmission.

Part of a structure of the intermediate shielding member 132 is embedded in the insulating structure 14, which not only enhances stability of the intermediate shielding member 132, but also avoids loosening or displacement that may occur in a vibration or impact environment through a fixing function of the insulating structure 14. Part of the structure of the intermediate shielding member 132 may extend out of the insulating structure 14 to facilitate connection with a corresponding part.

For example, the intermediate shielding member 132 is, for example, provided with two first protrusions 1321 symmetrically disposed along the second direction of the connector 1, and the first protrusion 1321 may extend out of the insulating structure 14 to abut against the shell structure 15, thereby achieving a reliable grounding connection. The design not only enhances an electrical safety of the connector 1, but also helps to guide possible electromagnetic interference to the ground, further improving the electromagnetic compatibility of the connector 1.

As another example, the intermediate shielding member 132 is, for example, further provided with two second protrusions 1322 symmetrically disposed along the second direction of the connector 1, the second protrusion 1322 may extend out of the insulating structure 14, and the second protrusion 1322 may be in close contact with a corresponding part on the male connector to ensure stable transmission of signals. The design not only meets signal transmission needs of the connector 1, but also effectively avoids an impact of electromagnetic interference on signal quality through an isolating function of the intermediate shielding member 132.

Through a detachable assembly structure of the outer shielding member 131, an electromagnetic shielding and signal transmission function of the intermediate shielding member 132, and a dual design of grounding and signal transmission, the shielding structure 13 in the embodiment successfully creates a high-performance, high-stability connector 1. The connector not only may effectively improve the electromagnetic compatibility, but also may ensure the purity and stability of signal transmission, providing a strong guarantee for reliable operation of modern electronic devices.

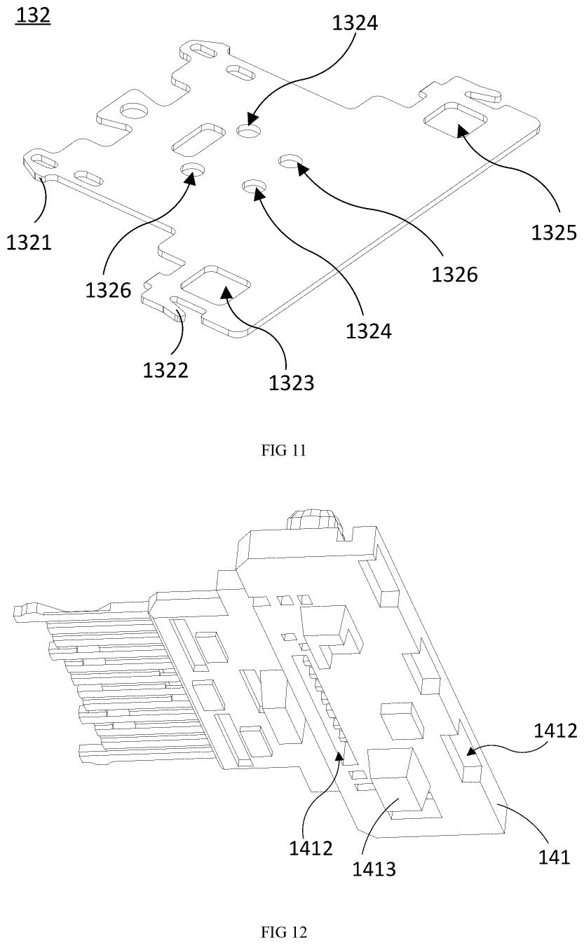

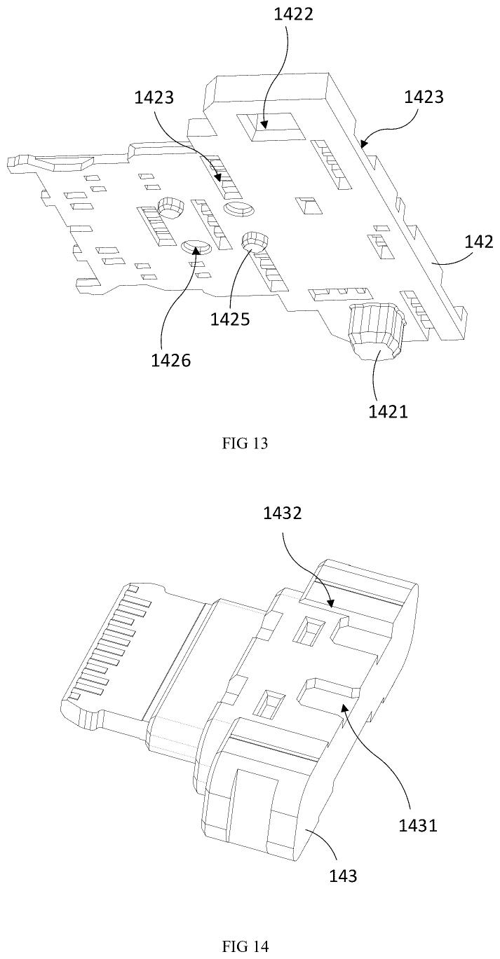

In some exemplary embodiments, as shown in FIG. 3 to FIG. 14, the insulating structure 14 is made of a material with a high insulation performance, and a main function of the insulating structure 14 is to isolate different signal terminals in the terminal assembly 16, prevent signal interference, and ensure pure transmission of signals.

The insulating structure 14, for example, includes a first insulating member 141, a second insulating member 142, and a third insulating member 143 which cooperate together to jointly construct an insulating barrier of the connector 1. The first insulating member 141 and the second insulating member 142 are arranged at intervals along the thickness direction of the connector 1 and are attached to two sides of the intermediate shielding member 132 to fix the intermediate shielding member 132.

The first insulating member 141 is configured to support and fix the first main body 16111 of the first conductive terminal 161, and may cover part of a structure of the first main body 16111 to facilitate fixing of the first main body 16111 and improve stability of the first conductive terminal 161.

It can be understood that, a function and an effect of the second insulating member 142 are the same as or similar to those of the above-mentioned first insulating member 141, the second insulating member 142 is configured to support and fix the second main body 16211 of the second conductive terminal 162, and the second insulating member 142 may cover part of a structure of the second main body 16211 to facilitate fixing of the second main body 16211 and improve stability of the second conductive terminal 162.

The third insulating member 143 wraps the first insulating member 141 and the second insulating member 142 by injection molding, which not only achieves integrity of the connector 1, but also enhances an insulation effect through tight wrapping. In addition, the third insulating member 143 may also wrap a partial area of the terminal assembly 16 to play an additional supporting and fixing role.

In the embodiment, as shown in FIG. 3 to FIG. 14, the first insulating member 141 has a first limiting through-hole 1411, the second insulating member 142 has a first limiting block 1421, the intermediate shielding member 132 is provided with a first penetrating through-hole 1323, and the first limiting block 1421 may pass through the first penetrating through-hole 1323 and extend into the first limiting through-hole 1411 for a positioning plug-in connection to achieve interlocking.

To fit other components, the first insulating member 141 is also provided with some limiting structures or recessed hole structures to achieve adaptability of various components in the connector 1.

For example, the first insulating member 141 is also provided with a plurality of first avoidance recesses 1412, and the plurality of first avoidance recesses 1412 can expose part of the first conductive terminal 161, reducing obstruction of signal transmission by insulating materials. A position of the first avoidance recess 1412 may be adaptively designed according to actual situations.

For example, the first insulating member 141 is also provided with a plurality of first protrusions 1413, the first protrusion 1413 may be embedded in the third insulating member 143 and plays a role of supporting and mutual restraint with the third insulating member 143, improving reliability and stability of a connection between the first insulating member 141 and the third insulating member 143.

For example, the first insulating member 141 is also provided with a plurality of first positioning posts 1415, the first positioning post 1415 cooperates with the intermediate shielding member 132, the intermediate shielding member 132 is, for example, provided with a plurality of first positioning holes 1324, and the first positioning posts 1415 are connected to the first positioning holes 1324 respectively, improving stability of the first insulating member 141 when installed in the intermediate shielding member 132. There may be, for example, two first positioning posts 1415 disposed along a diagonal line between the first direction and the second direction, which may achieve a fool-proofing design. It should be noted that, the second insulating member 142 may also be provided with a corresponding first jack 1426, and the first positioning post 1415 is inserted into the corresponding first jack 1426 to further achieve interlocking.

In the embodiment, as shown in FIG. 3 to FIG. 14, it may be understood that, the interlocking is not limited to be achieved in the above-mentioned manner. In some examples, the second insulating member 142 is provided with a second limiting through-hole 1422, the first insulating member 141 is provided with a second limiting block 1414, the intermediate shielding member 132 is provided with a second penetrating through-hole 1325, and the second limiting block 1414 passes through the second penetrating through-hole 1325 and is plug-in connected to the second limiting through-hole 1422 to achieve interlocking. The first limiting block 1421 and the second limiting block 1414 are disposed separately on two sides along the second direction of the connector 1, so that interlocking may be achieved on both sides, improving smoothness during connection.

In order to fit other components, the second insulating member 142 is also provided with some limiting structures or recessed hole structures to achieve adaptability of various components in the connector 1.

For example, the second insulating member 142 is also provided with a plurality of second avoidance recesses 1423, and the plurality of second avoidance recesses 1423 can expose part of the second conductive terminal 162, reducing obstruction of the signal transmission by the insulating materials.

For example, the second insulating member 142 is also provided with a plurality of second protrusions 1424, the second protrusion 1424 may be embedded in the third insulating member 143, and the second protrusion 1424 plays a role of supporting and mutual restraint with the third insulating member 143, improving reliability and stability of a connection between the second insulating member 142 and the third insulating member 143.

For example, the second insulating member 142 is also provided with a plurality of second positioning posts 1425, the second positioning post 1425 cooperates with the intermediate shielding member 132, the intermediate shielding member 132 is, for example, provided with a plurality of second positioning holes 1326, and the second positioning posts 1425 are plug-in connected to the second positioning holes 1326 respectively, improving stability of the second insulating member 142 when installed in the intermediate shielding member 132. There may be, for example, two second positioning posts 1425 disposed along a diagonal line between the first direction and the second direction, which may achieve a fool-proofing design. It should be noted that, the first insulating member 141 may also be provided with a corresponding second jack 1416, and the second positioning post 1425 is inserted into the corresponding second jack 1416 to further achieve interlocking.

The third insulating member 143 may also wrap the terminal assembly 16 to play a supporting and fixing role. Moreover, a partial area of the terminal assembly 16 is in an exposed state to facilitate a contact-type connection with a male connector.

It may be understood that, the above-mentioned embedding groove 1431 and the limiting recess 1432 are both disposed on the third insulating member 143 to facilitate limiting connections with the connecting support body 174 and the limiting spring piece 13121, respectively.

The connector 1 in the embodiment, through a fine insulating member layout, an interlocking mechanism design, and optimized design details, successfully creates a high-performance and high-stability connector 1. The connector 1 not only may effectively isolate different signal terminals and prevent signal interference, but also may ensure pure transmission of signals and structural stability of the connector, providing a strong guarantee for reliable operation of modern electronic devices.

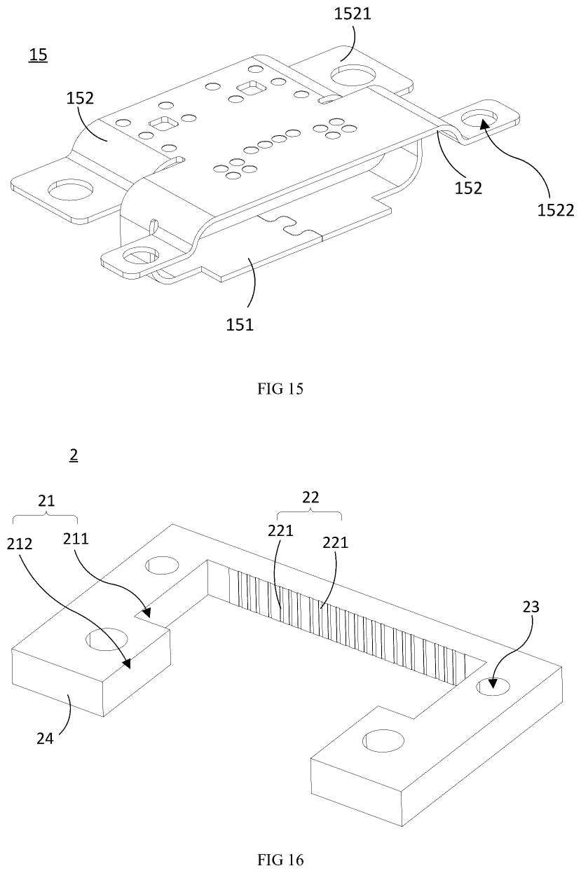

In some exemplary embodiments, as shown in FIG. 3 to FIG. 15, the shell structure 15, for example, includes a shell body 151 and at least one first shell support body 152, the shell body 151 is annular and is sleeved on the insulating structure 14 to be connected with the third insulating member 143 of the insulating structure 14 and the second portion 1312 of the shielding structure 13, respectively. The first protrusion 1321 of the intermediate shielding member 132 in the shielding structure 13 extends out of the insulating structure 14 and abuts against the shell body 151.

The first shell support body 152 is plate-like, and covers the first portion 1311 of the shielding structure 13. The first shell support body 152 has two connecting ears 1521 symmetrically disposed along the second direction of the connector 1, and the two connecting ears 1521 may be lapped onto the circuit board 2. The connecting ear 1521 is provided with a connecting hole 1522, and a fastener 3 may pass through the connecting hole 1522 to be connected with the circuit board 2 to achieve fixing of the connector 1. The fastener 3 is, for example, a screw, a bolt, or the like, and forms a screw connection with the circuit board 2 to improve reliability during connection.

It should be noted that, there may be one or two first shell support bodies 152, the two first shell support bodies 152 may be disposed separately along the first direction of the connector 1, and each of the first shell support bodies 152 is formed integrally with the shell body 151 to improve overall strength of the shell structure 15.

As shown in FIG. 1 to FIG. 3 and FIG. 16, the present disclosure also provides an accessory for an electronic device, including a fastener 3, a circuit board 2, and the connector 1 in any one of the above embodiments, the circuit board 2 is in contact-type connection with the connector 1, and a stable connection between the circuit board 2 and the connector 1 is achieved by using the connection manner in the above embodiments, thereby improving an overall performance and reliability of the electronic device.

Exemplarily, the circuit board 2 has a first side portion 24, the first side portion 24 is provided with an accommodating space 21, the accommodating space 21 penetrates through the circuit board 2 along a thickness direction of the circuit board 2, and a cross-sectional shape of the accommodating space 21 is adapted to a shape of the connector 1 to ensure that the connector 1 may be embedded in the accommodating space 21, so that both side surfaces of the circuit board 2 along the thickness direction of the connector 1 may be lower than a surface of the connector 1, reducing an overall thickness of the accessory for the electronic device and facilitating a thinning design of the electronic device.

A cross-sectional shape of the accommodating space 21 is, for example, a T-shape, which may restrict the connector 1, for example, in movement in the first direction and the second direction. Exemplarily, the accommodating space 21 includes a first accommodating region 211 and a second accommodating region 212, the first accommodating region 211 communicates with the second accommodating region 212, the first accommodating region 211 is configured to accommodate the second end 12 of the connector 1, and the second accommodating region 212 is configured to accommodate the first end 11 of the connector 1.

In the embodiment, as shown in FIG. 1 to FIG. 3 and FIG. 16, a conductive plate 22 is disposed on a side wall surface of the accommodating space 21 opposite to the first side portion 24, and the conductive plate 22 is disposed corresponding to the terminal assembly 16 of the connector 1 to achieve a contact-type electrical connection. The conductive plate 22, for example, includes a plurality of electrical connection bodies 221, the plurality of electrical connection bodies 221 are sequentially arranged at intervals along the side wall surface, and the electrical connection bodies 221 are in one-to-one correspondence and in contact-type connection with the first conductive terminal 161 and the second conductive terminal 162 of the connector 1.

The connecting ear 1521 of the shell structure 15 is attached to the circuit board 2, the circuit board 2 is provided with a screw hole 23, and one end of the fastener 3 passes through the connecting ear 1521 and is in threaded connection with the screw hole 23 to improve stability of a connection between the circuit board 2 and the connector 1. The fastener 3 is, for example, a screw or a bolt, which is simple and easy to implement. Two screw holes 23 may be provided to be consistent with the connecting ears 1521 to achieve balance.

It may be understood that, the circuit board 2 is designed according to specific functional requirements of an electronic device, and various electronic components, chips, and circuit wirings are integrated on the circuit board 2 to achieve specific electrical functions and signal processing, and the like.

The connector 1 adopts the connector 1 described in any one of the embodiments of the present disclosure, the connector 1 has excellent electrical connection performance and mechanical stability, and may ensure a stable and reliable connection with an external device or a power source. A design of the connector 1 considers compatibility with the circuit board 2, including factors such as a pin layout, a spacing, and a size, to ensure that the two can closely fit.

In a design stage of the circuit board 2, corresponding welding holes or sockets are reserved according to a welding pin layout of the connector 1. A position, a size, and a shape of the welding holes or the sockets accurately match welding pins of the connector.

The accessory for the electronic device provided in the embodiment, by integrating the high-quality connector 1 and circuit board 2, and adopting a precise assembly process, achieves a stable connection between the two. The accessory not only improves an overall performance and reliability of the electronic device, but also simplifies an assembly and maintenance process of the electronic device, reducing costs and time consumption.

The connector provided by the present disclosure changes an SMT welding method in the related art to a structure form where spring points are in contact with a circuit board, and achieves an electrical connection and mechanical fixing between the connector and the circuit board through an elastic deformation of an elastic arm, without a solder paste and a high-temperature furnace in the related art for welding, improving safety of the connector. At the same time, the connector also uses a fastener to fix the connector on the circuit board, further enhancing firmness and stability of the connection.

A welding-free manner of the connector in the present disclosure brings many advantages, for example, the welding-free manner effectively reduces an SMT process and labor costs, making an operation smoother, and improving production efficiency. Secondly, because there is no need to go through a heating process of a high-temperature furnace, the connector does not deform, thereby ensuring the performance and reliability of the connector. In addition, if the connector needs to be replaced, the connector is easily disassembled by simply unscrewing a screw, without a complicated welding operation, which is convenient and fast. Most importantly, the welding-free manner may also meet requirements of high-frequency signal transmission such as USB 4.0, providing a more reliable and efficient connection solution for future electronic products.

In summary, the welding-free manner of the connector has broad application prospects and important technical value in an electronic manufacturing field. With continuous development and upgrading of electronic products, the innovative connector fixing manner will be more widely applied and promoted.

It should be understood that the terms used herein are only for the purpose of describing specific exemplary embodiments and are not intended to be limiting. Unless the context clearly indicates otherwise, the singular forms “a”, “an” and “the” as used herein can also mean including plural forms. The terms “include”, “contain”, “comprise” and “have” are inclusive and thus indicate the presence of features, steps, operations, elements and/or components described, but do not exclude the presence or addition of one or more other features, steps, operations, elements, components, and/or combinations thereof. The method steps, procedures, and operations described herein are not interpreted as necessarily requiring them to be executed in the specific order described, unless the execution order is explicitly indicated. It should also be understood that additional or alternative steps may be used.

Although a plurality of elements, components, regions, layers and/or sections can be described herein with the terms first, second, third, and the like, they should not be limited by these terms. These terms may be only used to distinguish one element, component, region, layer or section from another ones. Terms such as “first” and “second” and other numerical terms do not imply sequence or order when used herein unless clearly indicated in the context. Accordingly, the first element, component, region, layer or section discussed below may be referred to as a second element, component, region, layer or section without departing from teachings of the exemplary embodiments.

The foregoing description is only the detailed description of the disclosure to enable a person skilled in the art to understand or implement the disclosure. Various modifications to these embodiments will be apparent to a person skilled in the art, and general principles defined herein may be implemented in other embodiments without departing from the spirit or scope of the disclosure. Thus, the disclosure is not limited to the embodiments shown herein, but conforms to the widest scope consistent with the principles and novel characteristics applied herein.

What is claimed is:

1. A connector assembled and connected to a circuit board, having a first end and a second end disposed opposite to each other, and comprising:
an insulating structure and a shielding structure that is disposed at the first end and is connected to the insulating structure;
a shell structure sleeved on an outer side of the insulating structure, adhering to the circuit board, and disassemblably connected to the circuit board through a fastener; and
a terminal assembly, part of a structure of which is disposed in the insulating structure, the terminal assembly comprising multiple sets of first conductive terminals and multiple sets of second conductive terminals, wherein the first conductive terminals and the second conductive terminals are located at the second end, extend out of the insulating structure, and are alternately arranged along a first direction of the connector, the first direction of the connector being perpendicular to a thickness direction of the connector,
wherein a first side portion of the circuit board is provided with a conductive plate, the connector is embedded in the circuit board, and the first conductive terminals and the second conductive terminals are in contact-type electrical connection with the conductive plate.

2. The connector according to claim 1, wherein the first conductive terminal comprises a plurality of first conductive bodies, and the plurality of first conductive bodies are sequentially arranged at intervals along the first direction of the connector; and
the first conductive body comprises a first main body and a first elastic arm, the first main body is connected to the first elastic arm, and the first elastic arm is configured to abut against the conductive plate, wherein the first main body is disposed in the insulating structure, and the first elastic arm extends out of the insulating structure.

3. The connector according to claim 2, wherein the first elastic arm comprises a first bending section, a first straight section, a first inclined section, and a second bending section that are sequentially connected, the first bending section bends relative to the first main body and extends along the thickness direction of the connector, and the first straight section bends relative to the first bending section and extends along a second direction of the connector;
the first inclined section is inclined relative to the first straight section, so that the first inclined section and the first straight section form a first preset included angle, wherein an extension direction of the first inclined section and an extension direction of the first bending section show opposite trends; and
the second bending section bends relative to the first inclined section and extends along the thickness direction of the connector, wherein each turning connection position in the first elastic arm is chamfered.

4. The connector according to claim 3, wherein the first elastic arm comprises a first turning arc section and a second turning arc section, the first inclined section is connected to the first turning arc section, the first turning arc section is configured to be chamfered for a first time, and the first turning arc section abuts against the conductive plate;
the first turning arc section is connected to the second turning arc section, the second turning arc section is configured to be chamfered for a second time, and a recess orientation of the first turning arc section is opposite to a recess orientation of the second turning arc section; and
the second turning arc section is connected to the second bending section.

5. The connector according to claim 2, wherein the second conductive terminal comprises a plurality of second conductive bodies, and the plurality of second conductive bodies are sequentially arranged at intervals along a second direction of the connector;
the second conductive body comprises a second main body and a second elastic arm, the second main body is disposed opposite to the first main body along the thickness direction of the connector; the second main body is connected to the second elastic arm and disposed in the insulating structure, and the second elastic arm extends out of the insulating structure and abuts against the conductive plate; and
a projection area of the second elastic arm along the first direction of the connector at least partially overlaps a projection area of the first elastic arm along the first direction of the connector.

6. The connector according to claim 5, wherein the second elastic arm comprises a third bending section, a second straight section, a second inclined section, and a fourth bending section that are sequentially connected, and the third bending section bends relative to the second main body and extends along the thickness direction of the connector;
the second straight section bends relative to the third bending section and extends along the second direction of the connector, and a projection area of the second straight section along the first direction of the connector does not overlap a projection area of the first elastic arm along the first direction of the connector;
the second inclined section is inclined relative to the second straight section, so that the second inclined section and the second straight section form a second preset included angle, wherein an extension direction of the second inclined section and an extension direction of the third bending section show opposite trends; and
the fourth bending section bends relative to the second inclined section and extends along the thickness direction of the connector, wherein each turning connection position in the second elastic arm is chamfered.

7. The connector according to claim 6, wherein the second elastic arm comprises a third turning arc section and a fourth turning arc section, the second inclined section is connected to the third turning arc section, the third turning arc section is configured to be chamfered for a third time, and the third turning arc section abuts against the conductive plate;
the third turning arc section is connected to the fourth turning arc section, the fourth turning arc section is configured to be chamfered for a fourth time, and a recess orientation of the third turning arc section is opposite to a recess orientation of the fourth turning arc section; and
the fourth turning arc section is connected to the fourth bending section, and projection areas of the third turning arc section and the fourth turning arc section along the first direction of the connector overlap the projection area of the first elastic arm along the first direction of the connector.

8. The connector according to claim 5, wherein the first elastic arm is a barb-like structure, and when the first conductive terminal is in contact-type connection with the conductive plate, the first elastic arm is deformed; and
wherein the second elastic arm is a barb-like structure, and when the second conductive terminal is in contact-type connection with the conductive plate, the second elastic arm is deformed.

9. The connector according to claim 5, wherein the connector comprises an isolating seat disposed at the second end, and the isolating seat is connected to the insulating structure, wherein
the isolating seat is provided with a plurality of first through-holes, and the first elastic arm and the second elastic arm are respectively inserted into the corresponding first through-holes.

10. The connector according to claim 9, wherein the isolating seat comprises an isolating body and at least one connecting support body connected to the isolating body; and
the isolating body is connected to the insulating structure along a second direction of the connector, and the connecting support body is connected to the insulating structure along the thickness direction of the connector.

11. The connector according to claim 10, wherein the at least one connecting support body comprises a first connecting support body and two second connecting support bodies, and the first connecting support body and the two second connecting support bodies are disposed separately on two sides along the thickness direction of the connector; and
the two second connecting support bodies are arranged at intervals along the first direction of the connector, and the first connecting support body and the two second connecting support bodies separately adheres to the insulating structure.

12. The connector according to claim 10, wherein the connecting support body is provided with a limiting catch, and the connecting support body is connected to the shielding structure in a limiting manner through the limiting catch.

13. The connector according to claim 12, wherein the limiting catch comprises a limiting protrusion and a wedge, and the limiting protrusion is fixedly connected to the wedge, wherein the wedge is located on a side of the limiting protrusion close to the first end.

14. The connector according to claim 12, wherein the shielding structure comprises an outer shielding member, and the outer shielding member is sleeved on the insulating structure, wherein
the outer shielding member is provided with at least one limiting hole, and the limiting hole is in a plug-in connection with the limiting catch.

15. The connector according to claim 14, wherein the outer shielding member is provided with at least one limiting spring piece, and the limiting spring piece is connected to the insulating structure in a limiting manner.

16. The connector according to claim 10, wherein the insulating structure is provided with at least one embedding groove, and the embedding groove is configured to accommodate the connecting support body.

17. The connector according to claim 15, wherein the insulating structure is provided with at least one limiting recess, and the limiting recess is connected to the limiting spring piece in a limiting manner.

18. An accessory for an electronic device, comprising a fastener, a circuit board, and the connector according to claim 1, wherein the fastener passes through the shell structure of the connector and is disassemblably connected to the circuit board;
the circuit board has a first side portion, the first side portion is provided with an accommodating space, the accommodating space penetrates through the circuit board along a thickness direction of the circuit board, and a side wall surface of the accommodating space disposed opposite to the first side portion is provided with a conductive plate; and
the accommodating space is configured to accommodate the connector, and the terminal assembly of the connector is in contact-type electrical connection with the conductive plate.

19. The accessory for an electronic device according to claim 18, wherein the conductive plate comprises a plurality of electrical connection bodies, and the plurality of the electrical connection bodies are arranged at intervals, so that the electrical connection bodies are in one-to-one correspondence and in contact-type electrical connection with the first conductive terminals and the second conductive terminals of the terminal assembly.
